(19) United States
(12) Patent Application Publication
(10) Pub. No.: US 2026/0165039 A1
(43) Pub. Date: Jun. 11, 2026

(54) SEMICONDUCTOR DEVICE AND METHOD FOR FABRICATING THE SAME

(71) Applicant: SK hynix Inc., Gyeonggi-do (KR)

(72) Inventors: Jeong Myeong KIM, Gyeonggi-do (KR); Cha Deok DONG, Gyeonggi-do (KR); Keo Rock CHOI, Gyeonggi-do (KR)

(21) Appl. No.: 19/243,623

(22) Filed: Jun. 19, 2025

(30) Foreign Application Priority Data
Dec. 10, 2024 (KR) 10-2024-0182439

(51) Int. Cl. H10N 70/20; H10B 61/00; H10B 63/00; H10N 50/01; H10N 50/10; H10N 50/85; H10N 70/00

(52) U.S. Cl. CPC H10N 70/25; H10B 61/10; H10B 63/22; H10N 50/01; H10N 50/10; H10N 50/85; H10N 70/043; H10N 70/826; H10N 70/841; H10N 70/884

(57) ABSTRACT

Disclosed are a semiconductor device and a method for fabricating the semiconductor device. The semiconductor device includes a plurality of memory cells. Each of the memory cells includes a memory layer; and a selector layer disposed over or below the memory layer, and configured to select the memory layer, the selector layer including an amorphous silicon layer which contains, as a dopant, a Group-14 element of a periodic table.

### CROSS-REFERENCE TO RELATED APPLICATIONS

The present application claims priority under 35 U.S.C 119(a) to

Korean Patent Application No. 10-2024-0182439, filed on Dec. 10, 2024, which is incorporated herein by reference in its entirety.

### BACKGROUND

### 1. Field

Embodiments of the present disclosure relate to a semiconductor technology, and more particularly, to a semiconductor device including a memory cell having a selector, and a method for fabricating the semiconductor device.

### 2. Description of the Related Art

Recent demands for miniaturization, low power consumption, high performance, and diversification of electronic devices require semiconductor devices capable of storing data in diverse electronic devices, such as computers, portable communication devices and the like. Researchers and the industry are studying to develop semiconductor devices that fulfill these requirements. Semiconductor devices that are being developed and investigated for these purposes include those capable of storing data by using the characteristics of switching between different resistance states according to the applied voltage or current, such as a Resistive Random Access Memory (RRAM), a Phase-change Random Access Memory (PRAM), a Ferroelectric Random Access Memory (FRAM), a Magnetic Random Access Memory (MRAM), an E-fuse and the like.

### SUMMARY

Embodiments of the present disclosure are directed to a semiconductor device that may have improved selector characteristics of a memory cell, and a method for fabricating the semiconductor device.

In accordance with an embodiment of the present disclosure, a semiconductor device includes a plurality of memory cells, wherein each of the memory cells includes a memory layer; and a selector layer disposed over or below the memory layer to select the memory layer, the selector layer including an amorphous silicon layer which contains, as a dopant, a Group-14 element of a periodic table.

In accordance with another embodiment of the present disclosure, a method for fabricating a semiconductor device with a selector layer included in each of a plurality of arrayed memory cells to control electrical access to a corresponding memory cell includes: forming an amorphous silicon layer as the selector layer over a substrate, the amorphous silicon layer containing, as a first dopant, a Group-14 element of a periodic table as the selector layer over a substrate; and performing an annealing process at a temperature lower than a temperature of crystallization of the amorphous silicon layer.

### BRIEF DESCRIPTION OF THE DRAWINGS

FIG. 1A is a perspective view illustrating a semiconductor device in accordance with an embodiment of the present disclosure.

FIG. 1B is a cross-sectional view illustrating the semiconductor device in accordance with an embodiment of the present disclosure.

FIG. 2 illustrates a structure of a selector unit in accordance with an embodiment of the present disclosure.

FIG. 3 illustrates an operation of the selector unit shown in FIG. 2 in accordance with an embodiment of the present disclosure.

FIGS. 4A and 4B illustrate a structure of an amorphous silicon layer included in a semiconductor device in accordance with an embodiment of the present disclosure.

FIGS. 5A to 5H are cross-sectional views illustrating a semiconductor device and a method for fabricating the same in accordance with an embodiment of the present disclosure.

### DETAILED DESCRIPTION

Hereinafter, the diverse embodiments of the present disclosure will be described in detail with reference to the attached drawings.

Embodiments of the present disclosure will be described below in more detail with reference to the accompanying drawings. The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art. Throughout the disclosure, like reference numerals refer to like parts throughout the various figures and embodiments of the present disclosure.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

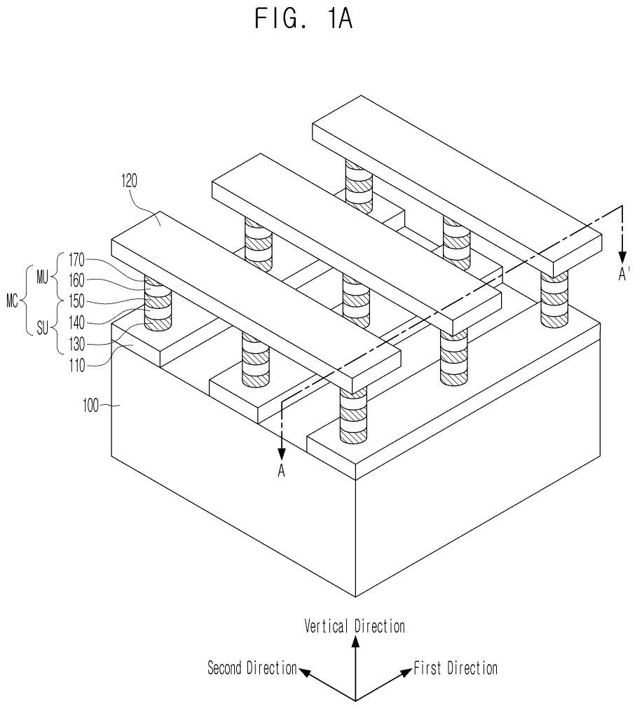

FIG. 1A is a perspective view illustrating a semiconductor device in accordance with an embodiment of the present disclosure. FIG. 1B is a cross-sectional view illustrating the semiconductor device in accordance with the embodiment of the present disclosure. FIG. 1B shows a cross-sectional view taken along a line A-A′ shown in FIG. 1A.

Referring to FIGS. 1A and 1B, the semiconductor device in accordance with the embodiment of the present disclosure may include a substrate 100, a plurality of first interconnections 110 disposed over the substrate 100 and extending in a first direction, a plurality of second interconnections 120 disposed over the first interconnections 110 and extending in a second direction that intersects with the first direction (for example, substantially perpendicular to the first direction), and a plurality of memory cells MC disposed between the first interconnections 110 and the second interconnections 120 to overlap with the intersection areas between the first interconnections 110 and the second interconnections 120. Here, the first direction and the second direction may mean directions substantially parallel to the surface of the substrate 100. A direction substantially perpendicular to the surface of the substrate 100 may be, hereinafter, referred to as a vertical direction.

The substrate 100 may include a semiconductor material such as silicon. Also, a selected predetermined lower structure (not shown) may be formed in the substrate 100. For example, an integrated circuit for driving a first interconnection 110 and/or a second interconnection 120 may be formed in the substrate 100.

A plurality of the first interconnections 110 may be disposed to be spaced apart from each other in the second direction. The first interconnection 110 may include diverse conductive materials, for example, metals such as platinum (Pt), tungsten (W), aluminum (Al), copper (Cu), tantalum (Ta) and the like, metal nitrides such as titanium nitride (TiN), tantalum nitride (TaN) and the like, or a combination thereof, and the first interconnection 110 may have a single-layer structure or a multi-layer structure.

A plurality of the second interconnections 120 may be disposed to be spaced apart from each other in the first direction. The second interconnection 120 may include diverse conductive materials, for example, metals such as platinum (Pt), tungsten (W), aluminum (Al), copper (Cu), tantalum (Ta) and the like, metal nitrides such as titanium nitride (TiN), tantalum nitride (TaN) and the like, or a combination thereof, and the second interconnection 120 may have a single-layer structure or a multi-layer structure. One among the first interconnection 110 and the second interconnection 120 may function as a word line, and the other may function as a bit line. Although this embodiment of the present disclosure illustrates a cross-point structure of one layer, a cross-point structure of two or more layers may be stacked in a vertical direction.

Each of the memory cells MC may include a memory unit MU, which is a portion where data are actually (for example, physically) stored, and a selector unit SU that controls access to the memory unit MU. For example, the memory cell MC may include a stacked structure of a first electrode layer 130, a selector layer 140, a second electrode layer 150, a memory layer 160, and a third electrode layer 170. In the illustrated embodiment, the selector unit SU may include the first electrode layer 130, the selector layer 140, and the second electrode layer 150. The memory unit MU may include the second electrode layer 150, the memory layer 160, and the third electrode layer 170. The second electrode layer 150 may be shared by the selector unit SU and the memory unit MU.

The semiconductor device may include an inter-layer dielectric layer 180 formed between the memory cells MC. The inter-layer dielectric layer 180 may be formed to have a thickness that sufficiently fills the space between the memory cells MC and covers an upper portion of the semiconductor device.

The first electrode layer 130 and the third electrode layer 170 may be disposed at both ends of the memory cell MC, that is, at the bottom and the top, respectively, and may function to transfer a voltage or current required for an operation of the memory cell MC. The second electrode layer 150 may function to electrically connect the selector layer 140 and the memory layer 160 to each other while physically separating them from each other. The first electrode layer 130, the second electrode layer 150, and/or the third electrode layer 170 may include diverse conductive materials, for example, metals such as platinum (Pt), tungsten (W), aluminum (Al), copper (Cu), tantalum (Ta), titanium (Ti) and the like, metal nitrides such as titanium nitride (TiN), tantalum nitride (TaN) and the like, or a combination thereof. Also, each of the first electrode layer 130, the second electrode layer 150, and the third electrode layer 170 may include a carbon electrode.

The memory layer 160 may function to store data in diverse ways. For example, the memory layer 160 may include a memory layer that stores different data by switching between different resistance states according to the voltage or current supplied through the upper and lower ends of the memory layer 160. The memory layer may have a single-layer structure or a multi-layer structure including diverse materials used in a Resistive Random Access Memory (RRAM), a Phase-change Random Access Memory (PRAM), a Ferroelectric Random Access Memory (FRAM), a Magnetic Random Access Memory (MRAM), and the like, for example, metal oxides such as transition metal oxides, perovskite-based materials and the like, phase-change materials such as chalcogenide-based materials and the like, ferroelectric materials, ferromagnetic materials, and the like.

The memory layer 160 may include one or more of a lower layer, a free layer, a tunnel barrier layer, a fixed layer, a magnetic compensation layer, and a capping layer (not separately shown).

In some embodiments, the free layer (which may also be called a storage layer) may store different data based on a changeable magnetization direction. The fixed layer (which may also be called a reference layer) may have a fixed magnetization direction and may be contrasted with the magnetization direction of the free layer. The free layer and the fixed layer may have a single-layer structure or a multi-layer structure including a ferromagnetic material. For example, the free layer and the fixed layer may include an alloy mainly formed of iron (Fe), nickel (Ni) or cobalt (Co), such as an iron-platinum (Fe—Pt) alloy, an iron-palladium (Fe—Pd) alloy, a Co—Pd alloy, a Co—Pt alloy, a Fe—Ni—Pt alloy, a Co—Fe—Pt alloy, a Co—Ni—Pt alloy, a Fe—Pd alloy, a Co—Pd alloy, a Co—Pt alloy, a Fe—Ni—Pt alloy, a Co—Fe—Pt alloy, a Co—Ni—Pt alloy, a cobalt-iron-boron (Co—Fe—B) alloy, and the like, or may include a stacked structure such as Co/Pt or Co/Pd. The magnetization directions of the free layer and the fixed layer may be substantially perpendicular to the surfaces of the layers. In other words, the magnetization direction of the free layer may vary between a top-down direction and a bottom-up direction, and the magnetization direction of the fixed layer may be fixed to the top-down direction or the bottom-up direction. The magnetization direction of the free layer may be changed due to the spin transfer torque. The relative positions of the free layer and the fixed layer may vary diversely with a tunnel barrier layer interposed between them. For example, the fixed layer may be disposed below the tunnel barrier layer, and the free layer may be disposed over the tunnel barrier layer.

The tunnel barrier layer may enable tunneling of electrons between the free layer and the fixed layer during a write operation that changes the resistance state of the variable resistor element, thereby changing the magnetization direction of the free layer. The tunnel barrier layer may include a dielectric oxide, such as magnesium oxide (MgO), calcium oxide (CaO), strontium oxide (SrO), titanium oxide (TiO), vanadium oxide (VO), niobium monoxide (NbO), and the like. The free layer, the tunnel barrier layer, and the fixed layer may form an MTJ structure.

The selector layer 140 may be implemented as a thin layer in the memory cell, and may have a function of preventing current leakage that may occur between the memory cells MC that share the first interconnection 110 or the second interconnection 120 while controlling the electrical access to one memory cell among a plurality of memory cells that are arrayed. To this end, the selector layer 140 may have the threshold switching characteristics of blocking off the current or holding current to hardly (for example, negligible) flow when the level of the voltage supplied to the upper and lower ends of the selector layer 140 is less than a predetermined threshold voltage level, and then letting the current flow rapidly (or freely) at a voltage level which is greater than or equal to the threshold voltage level. In other words, the selector layer 140 may be turned on at a voltage level which is equal to or higher than the threshold voltage level, and may be turned off at a voltage level which is lower than the threshold voltage level. For example, the selector layer 140 may include a dielectric material into which a dopant is implanted. According to an embodiment of the present disclosure, the selector layer 140 may include an amorphous silicon layer that is doped with a Group-14 element of the periodic table, e.g., germanium (Ge). According to yet another embodiment of the present disclosure, the selector layer 140 may be doped with a Group-15 element of the periodic table, e.g., arsenic (As), by performing an additional ion implantation process into the amorphous silicon layer that is doped with the Group-14 element of the periodic table.

Although FIGS. 1A and 1B show a memory cell MC having a stacked structure of the first electrode layer 130, the selector layer 140, the second electrode layer 150, the memory layer 160, and the third electrode layer 170, the concept and spirit of the present disclosure are not limited thereto, and the layer structure of the memory cell MC may be modified diversely. For example, at least one among the first electrode layer 130, the second electrode layer 150, and the third electrode layer 170 may be omitted. For example, the memory cell MC may include the selector layer 140, the first electrode layer 130 disposed below the selector layer 140, and the third electrode layer 170 disposed over the selector layer 140. For example, the first electrode layer 130 disposed below the selector layer 140 may include titanium nitride (TiN), and the third electrode layer 170 disposed over the selector layer 140 may include a carbon (C) electrode. Also, for example, the vertical positions of the selector layer 140 and the memory layer 160 may be switched. Also, for example, the memory cell MC may further include one or more layers (not shown) to improve the characteristics or the process.

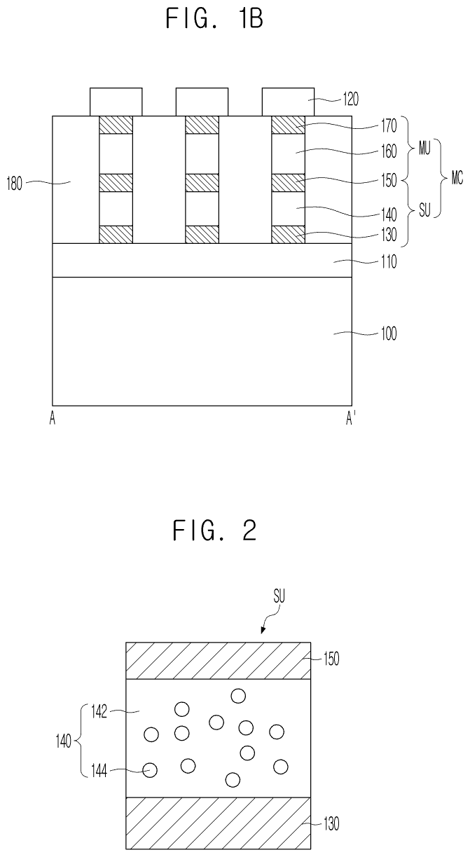

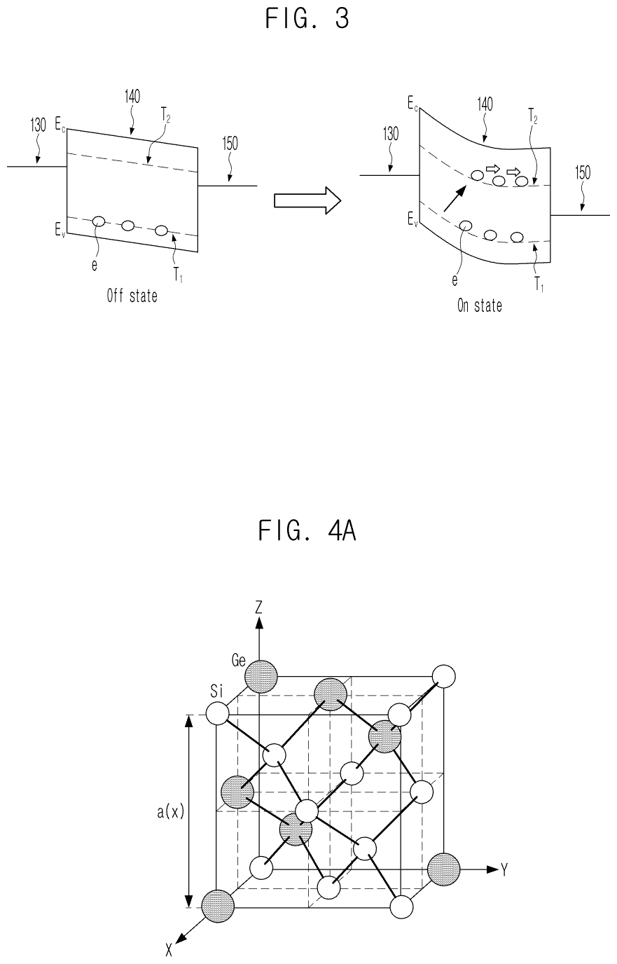

The selector unit SU including the selector layer 140 and the operation of the selector unit SU will be described in detail with reference to FIGS. 2 and 3 below.

FIG. 2 is a cross-sectional view illustrating the selector unit SU in accordance with the embodiment of the present disclosure.

Referring to FIG. 2, the selector unit SU may include a first electrode layer 130, a selector layer 140, and a second electrode layer 150.

As described above, the first electrode layer 130 and the second electrode layer 150 may include diverse conductive materials, such as metals, metal nitrides, and the like. The first electrode layer 130 and the second electrode layer 150 may be formed of the same material and thus they may have the same work function. For example, the first electrode layer 130 and the second electrode layer 150 may include titanium nitride (TiN) having a work function of approximately 4.4 to 4.6 eV. However, the concept and spirit of the present disclosure are not limited thereto, and the first electrode layer 130 and the second electrode layer 150 may be formed of different materials to have different work functions.

The selector layer 140 may include a dielectric material layer 142, and a dopant 144 which is implanted into the dielectric material layer 142. The dielectric material layer 142 may include a dielectric material having a relatively wide band gap, for example, a dielectric material having a band gap of approximately 5.0 eV or higher. For example, the dielectric material layer 142 may include a silicon-containing dielectric material such as silicon oxide, silicon nitride, silicon oxynitride and the like, a dielectric metal oxide, a dielectric metal nitride, or a combination thereof. For example, an oxide layer such as SiO₂ may be formed by mixing a source gas containing silicon (Si) and oxygen (O) through a method such as Chemical Vapor Deposition (CVD), Physical Vapor Deposition (PVD), or Atomic Layer Deposition (ALD). There may be a deep trap whose energy level is closer to the energy level of a valence band than to the energy level of a conduction band of the dielectric material layer 142 in the dielectric material layer 142. The dopant 144 may serve to create a shallow trap that provides a path for conductive carriers, such as electrons or holes, to migrate in the dielectric material layer 142. The shallow trap may have an energy level which is closer to the energy level of a conduction band than to the energy level of a valence band of the dielectric material layer 142. The dopant doped into the selector layer 140 may include an N-type or P-type dopant and may be implanted by an ion implantation process. For example, when the dielectric material layer 142 contains silicon, the dopant 144 may include a Group-14 element of the periodic table having a d electron in the orbital electron configuration. For example, the dopant 144 may include a Group-14 element of the periodic table, such as carbon (C), silicon (Si), germanium (Ge), or tin (Sn).

Also, when the dielectric material layer 142 contains silicon (Si), the dopant 144 may further include a Group-15 element of the periodic table having a different valence from the valence of silicon (Si). For example, the dopant 144 may include a Group-15 element of the periodic table, such as nitrogen (N), phosphorus (P), arsenic (As), or antimony (Sb), together with a Group-14 element of the periodic table. For example, the dopant 144 may include germanium (Ge). The dopant 144 may further include arsenic (As), phosphorus (P), or antimony (Sb) together with germanium (Ge), and preferably, the dopant 144 may further include arsenic (As).

The dopant concentration and the ratio of amorphous silicon in the doped amorphous silicon layer may vary greatly according to the process conditions. The dopant concentration may be controlled by controlling the flow rate and hydraulic pressure of diborane (B₂H₆) and silane gas (SiₓH_{y}). For example, when the flow rate of diborane is increased, the dopant concentration may be increased, and conversely, when the flow rate of silane gas is increased, the ratio of amorphous silicon may be increased. When a doped amorphous silicon layer is generated by reacting diborane and silane gases under the temperature condition of approximately 300° C., the dopant 144 may have a concentration of approximately 10 wt % to 30 wt % in the doped amorphous silicon layer, and the amorphous silicon may have a concentration of approximately 90 wt % to 70 wt %. When the doped amorphous silicon layer is generated by reacting diborane and silane gases under the temperature condition of approximately 400° C., the diffusion of the dopant may become more active so that the dopant may be more easily doped into the amorphous silicon layer. Therefore, in that case, the dopant 144 may have a concentration of approximately 30 wt % to 90 wt % in the doped amorphous silicon layer, and the amorphous silicon may have a concentration of approximately 70 wt % to 10 wt %.

The operation of this selector unit SU is described below with reference to FIG. 3 in accordance with an embodiment of the present disclosure.

FIG. 3 illustrates an operation of the selector unit shown in FIG. 2. Referring to FIG. 3, in the off-state where no voltage is applied to the selector unit SU, conductive carriers, for example, electrons (e), may be trapped in the deep trap T1 of the selector layer 140.

FIG. 3 illustrates an energy band diagram for electrons in semiconductor in which E_{c} represents the energy level at the bottom of the conduction band and Eᵥ represents the energy level at the top of the valence band. When a voltage whose level is greater than or equal to the threshold voltage level is applied to the selector unit SU of the off-state through the first electrode layer 130 and the third electrode layer 150, an on-state in which the current flows through the selector unit SU may be realized. To be specific, when a voltage whose level is greater than or equal to the threshold voltage level is applied to the selector unit SU, the conductive carriers (e) trapped in the deep trap T₁ may jump to the shallow trap T₂ by thermal emission or tunneling, and a conduction path coupling the first electrode layer 130 and the third electrode layer 150 may be created as the conductive carriers (e) migrate through the shallow trap T₂.

When the voltage applied to the selector unit SU of the on-state is decreased, the number of the conductive carriers migrating from the deep trap T₁ to the shallow trap T₂ may also be decreased to turn off the selector unit SU again.

In this way, the selector unit SU may be turned on or off.

FIGS. 4A and 4B illustrate a structure of an amorphous silicon layer included in a semiconductor device in accordance with an embodiment of the present disclosure.

FIG. 4A is a local crystal model (displaying elements in a crystal in a cartesian coordinate system of X, Y, and Z axis) used for simulation of ion implantation into silicon (Si), SiGe alloy having an arbitrary germanium (Ge) content (α(x)), and pure germanium (Ge) (where 0≤x≤1). FIG. 4B illustrates an atomic structure of silicon (Si) and germanium (Ge), showing an orbital electron configuration of the ground state.

Referring to FIG. 4A, in the case of SiGe alloy, diverse material properties may be simulated by controlling the content (x) of germanium (Ge). Also, the performance of the semiconductor device may be analyzed by reflecting (for example, comparing the performance based on the presence and concentration of germanium) the conductivity and lattice properties of pure germanium (Ge). Since germanium (Ge) has d electrons (i.e. electrons in the d orbitals, such as those typically found in the d-block of the periodic table), its atomic structure may be more complicated than that of silicon, which may affect the band structure. The presence of d electrons may contribute to germanium (Ge) having a higher conductivity than that of silicon. Since the atomic radius of germanium (Ge) is approximately 122 pm (picometer), which is larger than the atomic radius of silicon which is approximately 111 pm, lattice strain may occur when germanium (Ge) is doped into silicon (Si) or a SiGe alloy is formed. Since the band gap of germanium (Ge), which is approximately 0.66 eV, is smaller than the band gap of silicon (Si), which is approximately 1.12 eV, at a particular temperature, germanium (Ge) may have more free electrons than silicon (Si), and may have a higher conductivity, which may be advantageous for a high-speed device or high-current application. For example, when germanium (Ge) is doped with arsenic (As), N-type semiconductor characteristics may be obtained. Therefore, it may be used for diverse electronic devices, such as transistors, optical devices and the like.

When silicon (Si) is doped with germanium (Ge), strained lattice may be formed due to the difference in the atomic radius. Since the atomic radius of germanium (Ge) is larger than that of silicon (Si), the silicon lattice may be compressed and strained. This strain may change the band structure and conductivity, and may improve electron mobility and device performance.

By using the properties of silicon (Si) and germanium (Ge), a strained lattice structure may be formed in the selector pattern 240C by doping germanium into amorphous silicon, and the leakage current or insulation properties of the selector pattern 240C may be controlled by controlling the amount of ion implantation of arsenic (As) to be further doped. Also, a fast and efficient selector pattern 240C may be designed by utilizing the high conductivity of germanium (Ge). Also, the strained lattice structure of germanium (Ge) may facilitate maintaining the electrical properties of the selector pattern 240C more uniformly.

Referring to FIG. 4B, silicon (Si) has an electron configuration of 1s22s22p63s23p2, and since the 3d orbital is empty, it does not have d electrons. Germanium (Ge) may have an electron configuration of 1s22s22p63s23p63d104s24p2, and 3d10 may represent the d electrons of germanium (Ge). In germanium (Ge), the d electrons may increase the atomic size and may affect the chemical and electrical properties. For example, the d electrons may contribute to the high electrical conductivity and band structure tuning of germanium (Ge). Silicon (Si) may have a relatively simple electronic structure because the d orbital is empty, and may have a lower electrical conductivity than that of germanium (Ge).

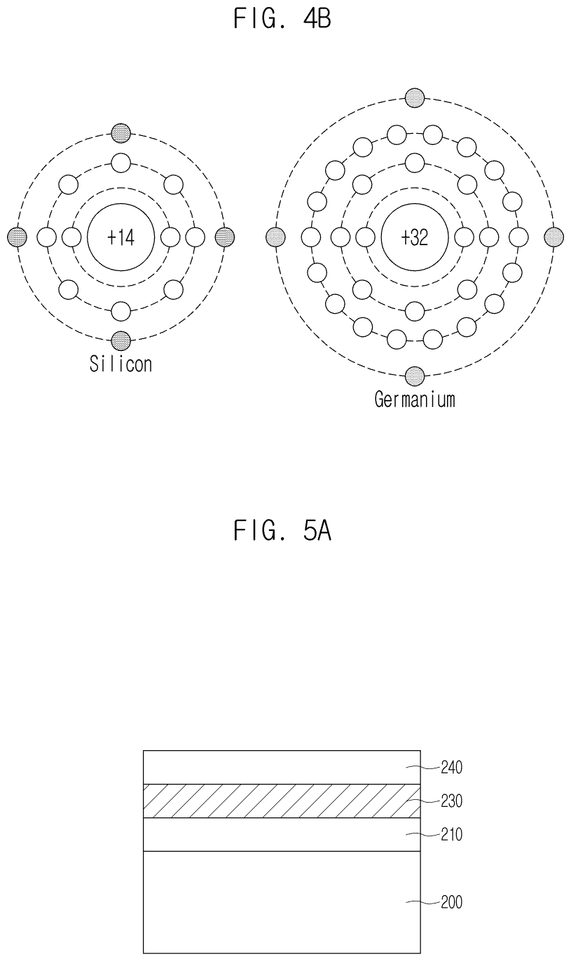

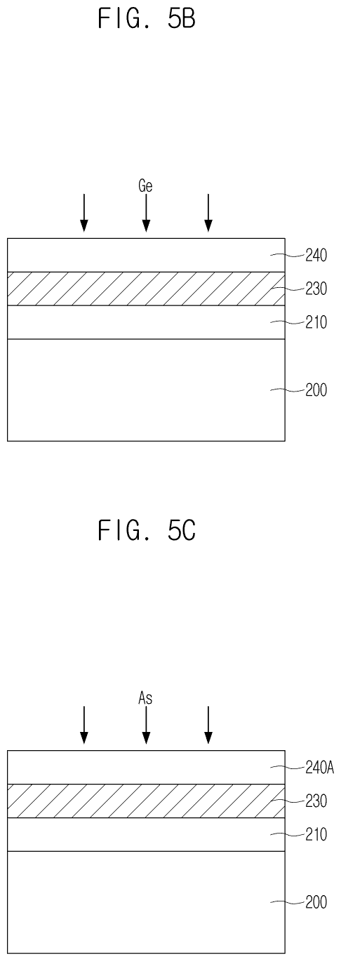

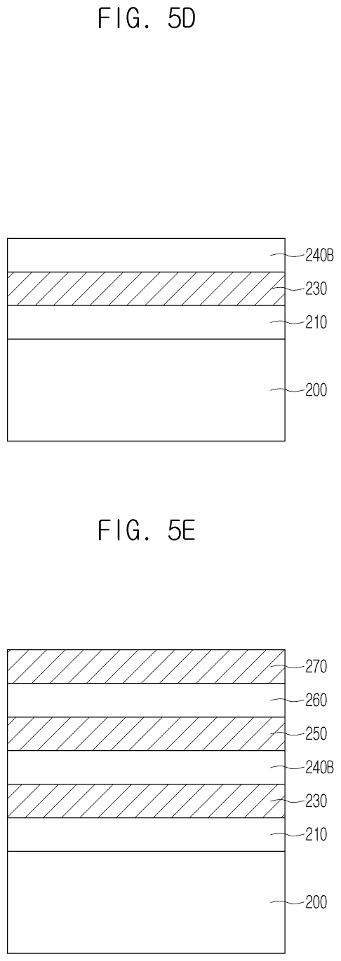

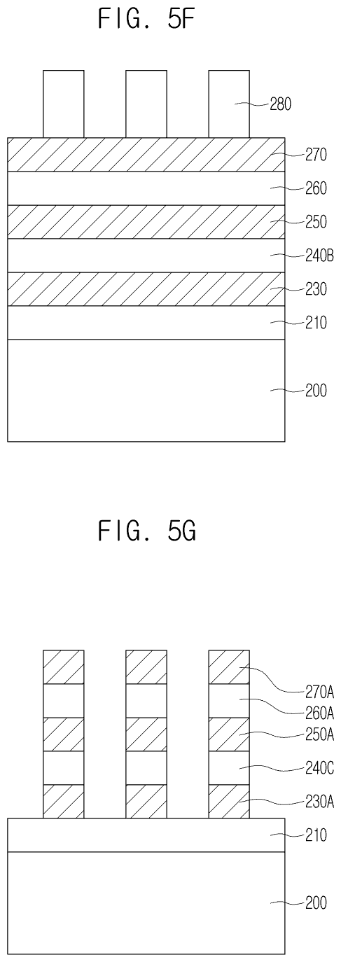

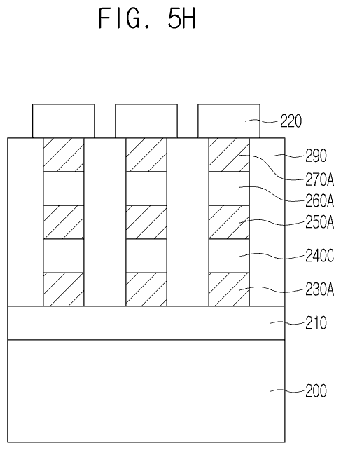

FIGS. 5A to 5H are cross-sectional views illustrating a semiconductor device and a method for fabricating the same in accordance with an embodiment of the present disclosure.

First, the method for fabricating the semiconductor device is described.

Referring to FIG. 5A, a substrate 200 with a predetermined lower structure formed therein may be provided. The substrate 200 may include selected diverse circuits. A first interconnection 210 may be formed over the substrate 200. The first interconnection 210 may be formed by forming a gap-fill layer (not shown) having a trench for forming the first interconnection 210 over the predetermined structure, and depositing a conductive layer for forming the first interconnection 210 in the trench. The first interconnection 210 may include diverse conductive materials, for example, metals such as platinum (Pt), tungsten (W), aluminum (Al), copper (Cu), tantalum (Ta) and the like, metal nitrides such as titanium nitride (TiN), tantalum nitride (TaN) and the like, or a combination thereof, and may have a single-layer structure or a multi-layer structure.

Subsequently, the first electrode layer 230 may be formed over the first interconnection 210. The first electrode layer 230 may be implemented as a TiN thin layer (for example, TiN thin film formed, for example, by physical vapor deposition (PVD) and CVD).

Subsequently, a boron-containing amorphous silicon layer may be formed as an initial selector layer 240 over the first electrode layer 230. The initial selector layer 240 may be formed by depositing an amorphous silicon layer through a Low-Pressure Chemical Vapor Deposition (LPCVD) process using a silicon source gas and a boron source gas. Here, the silicon source gas may include silane (SiH₄), dichlorosilane (SiH₂Cl₂), tetrachlorosilane (SiCl₄), trichlorosilane (SiHCl₃), or a mixture thereof, and the boron source gas may include diborane (B₂H₆), trimethylborane (B₃H₉), boron trimethyl ester (B(OCH₃)₃), boron trifluoride (BF₃), or a mixture thereof. For example, a silane gas (SiₓH_{y}), such as silane (SiH₄) and diborane (B₂H₆), may be mixed and used to form the initial selector layer 240, and the low-pressure chemical vapor deposition (CVD) process may provide a uniform thin layer and a low defect rate to improve the performance of the semiconductor device. Silane may be used as a main source of the silicon element, and diborane may be mixed with silane and utilized to form an amorphous silicon layer and improve doping uniformity.

Before the LPCVD process begins, the chamber may be made into a vacuum state, and the amorphous silicon layer may be formed under the conditions of a temperature of approximately 300° C. to approximately 400° C. and a low pressure state, for example, approximately 10 mTorr to 100 mTorr (millitorr). Here, the boron doping concentration may be adjusted to a desired level by controlling the flow rate ratio of the silicon source gas and the boron source gas. Through this process, the boron source gas and the silicon source gas may react with each other to form a uniform amorphous silicon layer over the substrate.

Also, the thickness and doping distribution of the layer may be maintained uniformly by precisely controlling the deposition time and the gas flow rate. The structural stability of the layer may be increased and the boron doping distribution may be optimized by additionally applying an annealing process to the formed amorphous silicon layer. As a result of this process, a uniform boron-doped amorphous silicon layer may be efficiently formed.

Subsequently, referring to FIG. 5B, a first dopant, for example, germanium (Ge), may be ion-implanted into the initial selector layer 240 to form a selector layer 240A that is doped with the first dopant. In addition to germanium (Ge), the first dopant may include a Group-14 element of the periodic table, for example, carbon (C), silicon (Si), or tin (Sn). Here, the initial selector layer 240 may be ion-implanted by ionizing the germanium atoms and then making the germanium ions collide with the initial selector layer 240 at a high speed and doping the initial selector layer 240 with the germanium ions. During the ion implantation, an ion implantation energy condition of approximately 20 keV to 80 keV and a concentration condition of approximately 1×10¹³ cm² to 1×10¹⁵ cm² may be adopted, and the ion implantation process may be performed at a room temperature to minimize the thermal damage.

The implanted germanium (Ge) ions may be unevenly distributed in the initial selector layer 240 and may be rearranged through a subsequent annealing process. The annealing process may be performed at a temperature of approximately 300° C. to 400° C. for several minutes to several hours to uniformly diffuse the implanted germanium (Ge) ions in the initial selector layer 240. The annealing process may be performed at a temperature lower than a temperature of crystallization of the amorphous silicon layer in order to maintain its amorphous phase. This annealing process may provide a structural stability to the first dopant-doped selector layer 240A and optimize the electrical properties of the first dopant-doped selector layer 240A.

Since the atomic radius and physical properties of germanium (Ge) are similar to those of silicon (Si) but have less aggressive effects, the ion implantation of germanium (Ge) may contribute to reducing the structural damage to the first dopant-doped selector layer 240A, compared to general arsenic-doped silicon oxide (As—SiO₂). Also, the resistance map uniformity of the amorphous silicon layer may be further improved through the process of doping germanium (Ge). As the resistance map uniformity is improved, the current flow of the selector pattern 240C may be stably maintained and the selector pattern 240C may be secured with a consistent operation.

Even though the initial selector layer 240 is doped with germanium (Ge), the Eot (Effective Oxide Thickness) and the leakage current range may be maintained at appropriate levels for the operation of the selector pattern 240C. The germanium (Ge) doping process may effectively control the leakage current while improving the conductivity. This is important especially in a semiconductor device that requires a high reliability. Also, doping the initial selector layer 240 with germanium (Ge) may be effective in controlling the initial resistance Rᵢₙᵢ due to the high conductivity and d electrons of germanium (Ge), and the generated selector pattern 240C may operate properly in diverse operating environments. The strong strained lattice structure generated through the germanium (Ge) doping process may stabilize the electrical properties of the selector pattern 240C more.

The ion implantation process using germanium (Ge) as the first dopant may improve the electrical properties and structural stability of the selector layer 240A that is doped with the first dopant, thereby ultimately realizing a high-performance selector pattern 240C. The germanium (Ge) doping process may provide the selector pattern 240C with superior performance in diverse aspects, such as resistance map uniformity, leakage current control, initial resistance adjustment and the like, compared to the existing arsenic-doped silicon oxide (As—SiO₂).

Subsequently, referring to FIGS. 5C and 5D, a selector layer 240B that is doped with the first and second dopants may be formed by ion-implanting arsenic (As) as the second dopant into the selector layer 240A that is doped with the first dopant. The second dopant may include a Group-15 element of the periodic table, such as nitrogen (N), phosphorus (P), or antimony (Sb), other than arsenic (As). According to one embodiment of the present disclosure, the first dopant may include germanium (Ge), and the second dopant may include arsenic (As), phosphorus (P), or antimony (Sb). According to another embodiment of the present disclosure, the second dopant may include arsenic (As).

According to an embodiment, phosphorus (P) or antimony (Sb) may be ion-implanted as the second dopant together with arsenic (As), or instead of arsenic (As). In other words, the selector layer 240B that is doped with the first and second dopants may be formed by ion-implanting germanium (Ge), which is a Group-14 element, as the first dopant into the initial selector layer 240, and ion-implanting arsenic (As), phosphorus (P), antimony (Sb), or a combination of two or more of them as the second dopant. This method may provide a foundation with physically optimized properties by using germanium (Ge) as the first dopant, while realizing diverse electrical properties by combining arsenic (As), phosphorus (P), or antimony (Sb) as the second dopant. Arsenic (As) may be advantageous in terms of electron mobility and doping efficiency, and since phosphorus (P) and antimony (Sb) have similar chemical properties to those of arsenic (As), they may provide complementary electrical properties. In particular, since phosphorus (P) may have a relatively small atomic radius and high electronegativity, the activation efficiency after implantation may be high. Therefore, the embodiment enable performance of a doping process more precisely than when phosphorus (P) is combined with arsenic (As). Antimony (Sb) has a larger atomic radius than that of arsenic (As), but has similar chemical properties and may be advantageous in that antimony (Sb) may form a stable current path even at a high doping concentration. Also, the selector layer 240B that is doped with the first and second dopants may include a combination of two or more selected from the group including germanium (Ge), arsenic (As), phosphorus (P), and antimony (Sb).

The ion-implantation of the second dopant may be performed in a direction substantially perpendicular to the surface of the substrate 200, and, additionally or alternatively, a tilted ion-implantation may also be performed. Also, the ion-implantation may be performed repeatedly several times. Electrical properties may be given to the semiconductor device which is fabricated by ion-implanting the second dopant, such as arsenic (As), into the amorphous silicon layer. The characteristics of the semiconductor device may vary appropriately by changing the concentration of the ion-implanted first and second dopants. By adjusting the implanted energy and angle, it is possible to control the concentration of the dopant and implant the dopant to a desired depth. The concentration of the dopant may be controlled according to the implantation conditions, such as energy, implantation time, and ion implantation rate, and for example, the concentration of the dopant may be controlled in the range of approximately 10% to 50% according to the implantation conditions. A high concentration of the dopant may contribute to forming a current path more easily, but on the other hand, it may also increase the leakage current. Therefore, it is desirable to control the concentration of the dopant in the above range. The ion implantation process may be performed repeatedly several times to evenly distribute the dopant. The repetition of this process may ensure that the conduction path is formed more stably in the amorphous silicon layer.

The dopant ions implanted during the ion implantation process may impact the crystal structure in the silicon layer due to the high energy. In particular, when a Group-15 element such as arsenic (As), phosphorus (P) or antimony (Sb) is implanted as a dopant into the amorphous silicon layer, a local re-crystallization phenomenon may occur at the implanted location. This re-crystallization may facilitate forming the conduction path more easily. This may improve the conductive properties of the selector unit in the on-state by mainly activating the conduction path more. The ion implantation process may control the electrical properties of the semiconductor device by implanting the second dopant into the amorphous silicon layer, and induce formation of the conduction path of the implanted dopant. This may allow the selector to have the desired current-voltage properties, and ease (for example, facilitate) formation of the conduction path.

The implantation damage caused by ion-implanting germanium (Ge), which is a Group-14 element of the periodic table, and arsenic (As), which is a Group-15 element, into the initial selector layer 240 may be relatively small (for example, with measurably negligible structural or secondary effects on the properties of the initial selector layer 240). This is because when arsenic and germanium (Ge) are doped into a silicon layer, defects that may occur in a solid material may be minimized. Therefore, the electrical properties of the finally formed selector pattern 240C may be stable and uniform. Also, the resistance map uniformity indicating that the doped material is uniformly distributed in the selector layer 240B that is doped with the first and second dopants may be improved. This may improve the electrical uniformity of the finally generated selector pattern 240C and facilitate a reduction in the fluctuation in the performance. Also, due to the doping of germanium (Ge) and arsenic (As), the Eot and leakage current range may be maintained at appropriate levels, and the Eot may not be increased. This is advantageous in obtaining desired electrical properties by adjusting the Eot and leakage current range values.

The doping of germanium (Ge) and arsenic (As) may be significant in improving the performance of the selector pattern 240C and controlling the electrical properties of the selector pattern 240C including the amorphous silicon layer containing boron. In particular, with uniform resistance distribution, appropriate leakage current, and adjustment of the Eot and leakage current range, to the embodiment enable maximized efficiency of the selector pattern 240C and provide properties suitable for industrially important applications.

According to this embodiment of the present disclosure, germanium (Ge), which is a Group-14 element of the periodic table, is ion-implanted first into the initial selector layer 240 as the first dopant, and then arsenic (As), which is a Group-15 element, is ion-implanted as the second dopant subsequently, but the order or the ion implantations may not be limited thereto. For example, in instances in which arsenic (As), which is a Group-15 element, is ion-implanted into the initial selector layer 240 as the first dopant and germanium (Ge), which is a Group-14 element, is ion-implanted as the second dopant, substantially the same effect may be obtained.

According to embodiments of the present disclosure, the selector layer 240B that is doped with the first and second dopants may have a thickness of approximately 50 Å to 150 Å, a thickness of approximately 80 Å to 120 Å, and, in a particular embodiment, a thickness of approximately 100 Å. When the selector layer 240B is too thin, it may not trap sufficient charges that the resistance may be lowered in the off-state and the leakage current may be increased. When the selector layer 240B is too thick, the conduction path may become excessively long in the on-state, which may reduce the current flow. Also, when the thickness of the selector layer 240B is too thin, switching may become unstable which may fluctuate the resistance more severely, and when it is too thick, the switching speed may be decreased. Since the selector layer 240B has a thickness of approximately 50 Å to 150 Å, this enables the disclosed embodiments to optimize the current flow by balancing the formations of charge traps and conduction path, effectively control the resistance, and maintain a fast switching speed while securing a stable switching operation.

The ion implantation process of the second dopant described with reference to FIGS. 5C and 5D may be omitted in the process of preparing the selector pattern 240C in accordance with the embodiment of the present disclosure. In other words, it is possible to fabricate a semiconductor device suitable for a specific purpose and characteristic only with the amorphous silicon layer into which the first dopant including a Group-14 element of the periodic table is implanted as the selector pattern 240C. However, when the second dopant including a Group-15 element of the periodic table is additionally implanted, the conductive path may be formed more easily, and thus the electrical properties of the selector may be enhanced.

Subsequently, referring to FIG. 5E, a second electrode layer 250, a memory layer 260, and a third electrode layer 270 may be formed over the selector layer 240B that is doped with the first and second dopants. The second electrode layer 250 and the third electrode layer 270 may be formed by a method of depositing a conductive material. The second electrode layer 250 may be realized (for example, prepared, deposited, formed, etc.) as a single TiN thin layer, and may alternatively be realized by stacking a carbon (C) thin layer and a TiN layer. Here, the carbon (C) thin layer may be formed at the interface between the selector layer 240B that is doped with the first and second dopants and the TiN layer, thereby improving the interface characteristics between the electrodes. Also, an SiN thin layer may be formed between the first electrode layer 230 and the selector layer 240B that is doped with the first and second dopants, and a carbon (C) thin layer may be formed between the selector layer 240B that is doped with the first and second dopants and the second electrode layer 250.

The memory layer 260 may be formed between the selector layer 240B that is doped with the first and second dopants and the third electrode layer 270, and may include a variable resistance layer. The variable resistance layer may store data by changing the resistance state according to the voltage and may perform a key function as a memory element.

The third electrode layer 270 may be formed over the second electrode layer 250 and the memory layer 260, and the third electrode layer 270 may be generally formed of a material that may sustain a high-temperature annealing process and has excellent conductivity. The third electrode layer 270 may be formed using a metal deposition process or a sputtering process. To be specific, the third electrode layer 270 may be formed by depositing a conductive metal thin layer, such as titanium nitride (TiN), tungsten (W), copper (Cu), or aluminum (Al).

In the process of forming the third electrode layer 270, it is important to maintain high deposition uniformity and conductivity, and in these instances, the metal layer may be formed to have a (for example, desired) selected thickness through a process, such as plasma sputtering or Chemical Vapor Deposition (CVD). After the third electrode layer 270 is formed, an additional annealing process or a patterning process may be performed to provide optimal electrical connection characteristics in the semiconductor device.

Referring to FIG. 5F, a hard mask layer 280 may be formed over the third electrode layer 270. The hard mask layer 280 may be formed by forming a material layer for the hard mask layer 280 and a photoresist pattern (not shown) and etching the material layer for the hard mask layer 280 with the photoresist pattern used as an etching barrier. The hard mask layer 280 may function as an etching barrier during the etching process for forming a memory cell MC and may include diverse materials capable of securing an etching selectivity with respect to the memory cell MC. For example, the material layer for the hard mask layer 280 may have a single-layer structure or a multi-layer structure including diverse dielectric materials such as silicon oxide, silicon nitride, silicon oxynitride and the like.

Referring to FIG. 5G, a memory cell MC including a third electrode pattern 270A, a memory pattern 260A, a second electrode pattern 250A, a selector pattern 240C, and a first electrode pattern 230A may be formed by using the hard mask layer 280 as an etching barrier and etching the third electrode layer 270, the memory layer 260, the second electrode layer 250, the selector layer 240B that is doped with the first and second dopants, and the first electrode layer 230. This etching process may be a process of selectively removing each layer into a desired shape and electrically and physically separating the layers from each other. In this process, the hard mask layer 280 may protect the underlying layer and may facilitate the formation of a proportionally precise pattern.

According to this embodiment of the present disclosure, the hard mask layer 280 may be removed in the process of etching the memory cell MC. According to another embodiment of the present disclosure, part or all of the hard mask layer 280 may remain and may be removed in the subsequent planarization process, which is described below.

Referring to FIG. 5H, an inter-layer dielectric layer 290 may be formed between the memory cells MC. The inter-layer dielectric layer 290 may be formed to have a thickness that sufficiently fills the space between the memory cells MC and covers the upper portion. The inter-layer dielectric layer 290 may have a single-layer structure or a multi-layer structure including diverse dielectric materials such as silicon oxide, silicon nitride, or a combination thereof.

Subsequently, a planarization process, such as a Chemical Mechanical Polishing (CMP) process, may be performed on the inter-layer dielectric layer 290 until the upper surface of the memory cell MC is exposed. In some instances, the hard mask layer 280 may not be completely removed but remain in the aforementioned memory cell MC etching process. The hard mask layer 280 that may remain after the memory cell MC etching may be removed in instances in which the planarization process is performed until the upper surface of the memory cell MC is exposed.

Subsequently, a plurality of second interconnections 220 extending in the second direction intersecting with the first direction, for example, the second direction shown FIG. 1A, may be formed over the memory cell MC and the inter-layer dielectric layer 290 while being coupled to the upper surface of the memory cell MC. The second interconnections 220 may be formed by depositing a conductive material and patterning the conductive material, and the space between the second interconnections 220 may be filled with a dielectric material (not shown).

The semiconductor device in accordance with the embodiment of the present disclosure, as illustrated in FIG. 5H, may be fabricated by the process described above.

Referring again to FIG. 5H, the semiconductor device in accordance with the embodiment of the present disclosure may include a selector pattern 240C including an amorphous silicon layer which contains, as a dopant, a Group-14 element of the periodic table and optionally a Group-15 element. The semiconductor device in accordance with the embodiment of the present disclosure may include a substrate 200, and a first interconnection 210, a first electrode pattern 230A, a selector pattern 240C, a second electrode pattern 250A, a memory pattern 260A, a third electrode pattern 270A, and a second interconnection 220 that are sequentially formed over the substrate 200, and may include an inter-layer dielectric layer 290 that covers between the memory cells.

The process structure illustrated in FIG. 5H may be substantially the same as the process structures illustrated in FIGS. 1A and 1B described above. In other words, the substrate 200, the first interconnection 210, the first electrode pattern 230A, the selector pattern 240C, the second electrode pattern 250A, the memory pattern 260A, the third electrode pattern 270A, and the second interconnection 220 may correspond to the substrate 100, the first interconnection 110, the first electrode layer 130, the selector layer 140, the second electrode layer 150, the memory layer 160, the third electrode layer 170, and the second interconnection 120 of FIG. 1A, respectively. Therefore, detailed description on the portion corresponding to that of the process structures of FIGS. 1A and 1B described above will be omitted herein.

When the selector pattern 240C of the semiconductor device is formed in accordance with one embodiment of the present disclosure, a Group-14 element of the periodic table, such as germanium (Ge), and a Group-15 element, such as arsenic (As), may be ion-implanted into the amorphous silicon layer, thereby providing a selector pattern having superior performance compared to the selector pattern using a typical arsenic (As)-doped silicon oxide layer.

Unique electrical properties compared to a typical selector pattern may be realized by forming a strong strained lattice structure in the selector layer and controlling the amount of arsenic (As) that is additionally ion-implanted based on the difference in the atomic radius and mass of silicon (Si) and germanium (Ge). This structure may provide a high conductivity and unique resistance characteristics to maximize the performance of the selector element requiring leakage current or insulation-like characteristics. Also, since the conductivity of germanium (Ge) is higher than that of silicon (Si), more efficient electrical performance may be achieved by controlling the amount of ion implantation of germanium (Ge) and appropriately combining the germanium (Ge) with another element that is also ion implanted, and the flexibility of the selector element may be increased through combination of diverse materials. In particular, co-ion implantation of arsenic (As) and germanium (Ge) may customize the operation characteristics of the selector element to reduce the leakage current or enhance the insulation characteristics.

Further, since the selector pattern 240C in accordance with the embodiment of the present disclosure may control the leakage current and the insulation characteristics by using dopants, it may be used in diverse electronic devices, such as a MOSFET element, a “0” & “1” pixel element, and a resistor-based memristor element. In particular, the disclosed embodiments may be suitable for advanced applications such as memory semiconductors, image sensors, and high-speed computation devices. By maximizing the electrical properties of the selector pattern 240C through the artificial strained lattice structure, the size of the device may be designed to be smaller, which may satisfy the needs of the modern semiconductor industry that requires high integration and light-weight (or weight minimized) components. Also, the method for fabricating a semiconductor device in accordance with the embodiment of the present disclosure may reduce the cost while improving the fabrication quality of the device by realizing a uniform thin layer and a low defect rate through a Low-Pressure Chemical Vapor Deposition (LPCVD) process. Also, for example, the co-ion implantation of germanium (Ge) and arsenic (As) may be integrated into the fabrication process without an additional complex procedure in the existing process line, thereby providing process flexibility.

According to the embodiment of the present disclosure, the semiconductor device and the method for fabricating the same may control the characteristics of the selector layer by using an amorphous silicon layer which contains a dopant including a Group-14 element of the periodic table as the selector layer, and improve the characteristics of the selector layer by forming a strained lattice structure in the selector layer.

While the present disclosure has been described with respect to the specific embodiments, it will be apparent to those skilled in the art that various changes and modifications may be made without departing from the spirit and scope of the invention as defined in the following claims.

What is claimed is:

1. A semiconductor device comprising a plurality of memory cells,
wherein each of the memory cells includes:
a memory layer; and
a selector layer configured to select the memory layer, the selector layer including an amorphous silicon layer which contains, as a dopant, a Group-14 element of a periodic table.

2. The semiconductor device of claim 1, wherein the amorphous silicon layer further contains, as the dopant, a Group-15 element of the periodic table.

3. The semiconductor device of claim 1, wherein the amorphous silicon layer, as the dopant, contains germanium (Ge).

4. The semiconductor device of claim 2, wherein the amorphous silicon layer, as the dopant, contains:
germanium (Ge); and
at least one selected from a group including phosphorus (P), arsenic (As), and antimony (Sb).

5. The semiconductor device of claim 2, wherein the amorphous silicon layer, as the dopant, contains germanium (Ge) and arsenic (As).

6. The semiconductor device of claim 2, wherein the dopant has a concentration of 10 wt % to 30 wt % in the amorphous silicon layer.

7. The semiconductor device of claim 2, wherein the dopant has a concentration of 30 wt % to 90 wt % in the amorphous silicon layer.

8. The semiconductor device of claim 1, further comprising:
a first electrode layer disposed below the selector layer; and
a second electrode layer disposed over the selector layer.

9. The semiconductor device of claim 8, wherein each of the first electrode layer and the second electrode layer includes a TiN thin layer.

10. The semiconductor device of claim 8, further comprising:
an SiN thin layer disposed between the first electrode layer and the selector layer; and
a carbon (C) thin layer disposed between the selector layer and the second electrode layer.

11. The semiconductor device of claim 1, wherein the selector layer has a thickness of 50 Å to 150 Å.

12. The semiconductor device of claim 1, wherein the selector layer is disposed over or below the memory layer.

13. A method for fabricating a semiconductor device with a selector layer included in each of a plurality of arrayed memory cells to control electrical access to a corresponding memory cell, the method comprising:
forming an amorphous silicon layer as the selector layer over a substrate, the amorphous silicon layer containing, as a first dopant, a Group-14 element of a periodic table; and
performing an annealing process at a temperature lower than a temperature of crystallization of the amorphous silicon layer.

14. The method of claim 13, further comprising ion-implanting a second dopant into the amorphous silicon layer containing the first dopant.

15. The method of claim 13, wherein the forming of the amorphous silicon layer includes:
depositing an amorphous silicon layer over the substrate; and
ion-implanting the first dopant.

16. The method of claim 14, wherein each of the first dopant and the second dopant has a concentration of 10 wt % to 30 wt % in the amorphous silicon layer.

17. The method of claim 14, wherein each of the first dopant and the second dopant has a concentration of 30 wt % to 90 wt % in the amorphous silicon layer.

18. The method of claim 13, further comprising forming an electrode layer over the selector layer.

19. The method of claim 13, wherein the selector layer is formed to have a thickness of 50 Å to 150 Å.

20. The method of claim 14, wherein the amorphous silicon layer contains, as the second dopant, a Group-15 element of the periodic table.

21. The method of claim 14, wherein:
the amorphous silicon layer contains, as the first dopant, germanium (Ge); and
the amorphous silicon layer contains, as the second dopant, at least one selected from a group including phosphorus (P), arsenic (As), and antimony (Sb).

22. The method of claim 14, wherein:
the amorphous silicon layer contains, as the first dopant, germanium (Ge); and
the amorphous silicon layer contains, as the second dopant, arsenic (As).
